(19) United States
(12) Patent Application Publication
(10) Pub. No.: US 2024/0188225 A1
(43) Pub. Date: Jun. 6, 2024

(54) GLASS COATING TO MINIMIZE ROUGHNESS INSIDE THROUGH GLASS VIAS

(71) Applicant: Intel Corporation, Santa Clara, CA (US)

(72) Inventors: Vinith BEJUGAM, Chandler, AZ (US); Rengarajan SHANMUGAM, Tempe, AZ (US); Srinivas PIETAMBARAM, Chandler, AZ (US); Mao-Feng TSENG, Tempe, AZ (US); Yonggang LI, Chandler, AZ (US)

(21) Appl. No.: 18/060,598

(22) Filed: Dec. 1, 2022

(51) Int. Cl. H05K 3/40; C23C 18/18; C23C 18/38; H05K 1/03; H05K 1/11; H05K 3/18

(52) U.S. Cl. CPC H05K 3/4038; C23C 18/1868; C23C 18/38; H05K 1/0306; H05K 1/115; H05K 3/181; H05K 2201/09563; H05K 2201/2081; H05K 2203/107

(57) ABSTRACT

A method for manufacturing a structured substrate is provided, the method including: forming a plurality of openings extending from a first surface of a substrate towards a second surface of the substrate, wherein the first surface is coplanar to the second surface, wherein the substrate comprises glass, and wherein each of the openings comprises a sidewall; forming a first layer at least on the sidewall of the openings; forming a second layer on the first layer, wherein the second layer comprises titanium; and depositing metal on the second layer to at least partially fill the openings.

### TECHNICAL FIELD

The present disclosure relates to manufacturing methods of panels having a plurality of vias.

### BACKGROUND

Substrates having filled through holes, e.g. through-glass-vias (TGV) formed using laser-assisted etching in HF or NaOH etching in glass substrates, can have a roughness, e.g. measured by confocal microscopy, in a range from about 400 μm to about 800 μm—see FIG. 4A showing the roughness Rz 406 in Nanometer (nm) and FIG. 4B showing the roughness Ra 404 in nm as a function of the pitch 402 of the HF-etched TGV measured at different position 408 of the substrate. This roughness may cause a forming of voids after filling the through holes to form the TGV 602, as can be seen by the step coverage of a seed layer on the sidewall 601, 603 (e.g. compare thickness of the seed layer (bright line in FIG. 6A) of the TGV 602 at the TGV center (603) shown in FIG. 6A. Also, sidewalls of the TGV 602 or edges of the substrate having a high roughness may be the source for crack propagation 604 in the substrate as shown in FIG. 6B. Laser parameters, e.g. laser intensity, may be adjusted to tune the roughness of the sidewall of the through holes. However, lower laser energies and intensities may lead to incomplete formation of a TGV, and may change other output characteristics such as taper.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a flow diagram of a method to manufacture a structured substrate;

FIG. 2A shows a schematic illustration of a structured substrate;

FIG. 2B shows a schematic cross-sectional view of a structured substrate;

FIGS. 3A to 3D show schematic cross-sectional views of a substrate in a method to manufacture the structured substrate;

FIGS. 4A and 4B show diagrams illustrating roughness values of sidewalls of the through holes;

FIG. 5A illustrates a surface without planarization layer;

FIG. 5B illustrates the surface of FIG. 5A after forming a planarization layer;

FIG. 6A shows and optical microscopy image of a glass substrate having through holes with high roughness sidewalls; and

FIG. 6B shows an image of a glass substrate having through holes with high roughness sidewalls.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

This disclosure addresses various methods for improving substrates having vias by reducing a roughness of the sidewalls of through holes after formation of the through holes in the substrate. A via is formed by forming a through hole in a substrate, reducing a roughness of the sidewall of the through hole, and filling the through hole with a filling structure. The filling structure may be formed on a seed layer applied to the sidewall. The reduced roughness of sidewalls provide an improved step coverage and may prevent a formation of voids in the filling structure of the through holes. Thus, the method provides better coverage of the seed layer by the filling structure at the center of the TGV and prevents voids in the filling structure. Alternatively, or in addition, a crack propagation in the substrate may be prevented or reduced. Alternatively, or in addition, interconnect quality and power delivery in a device having the substrate may be improved. Alternatively, or in addition electrical resistance in a device having the substrate may be improved.

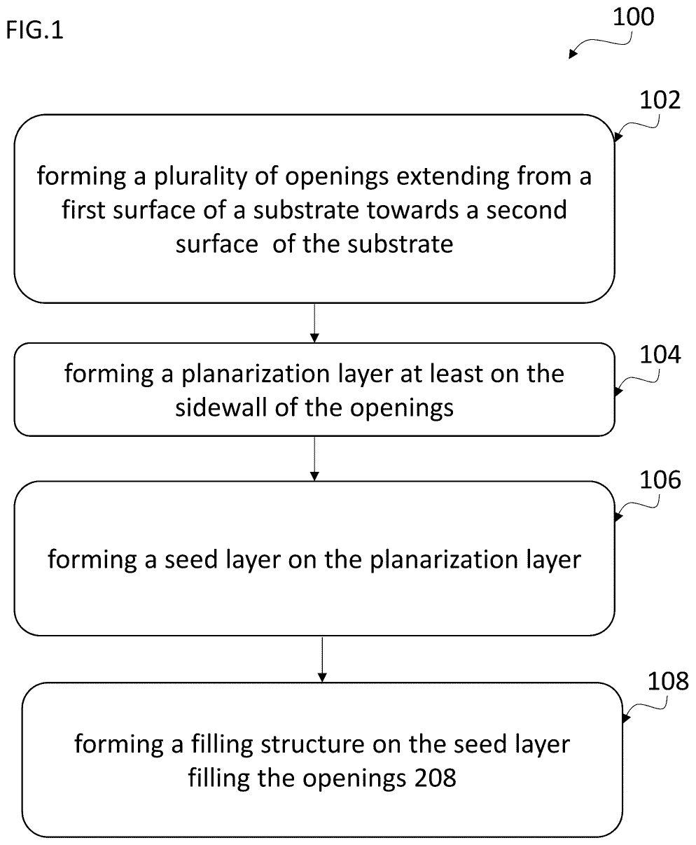

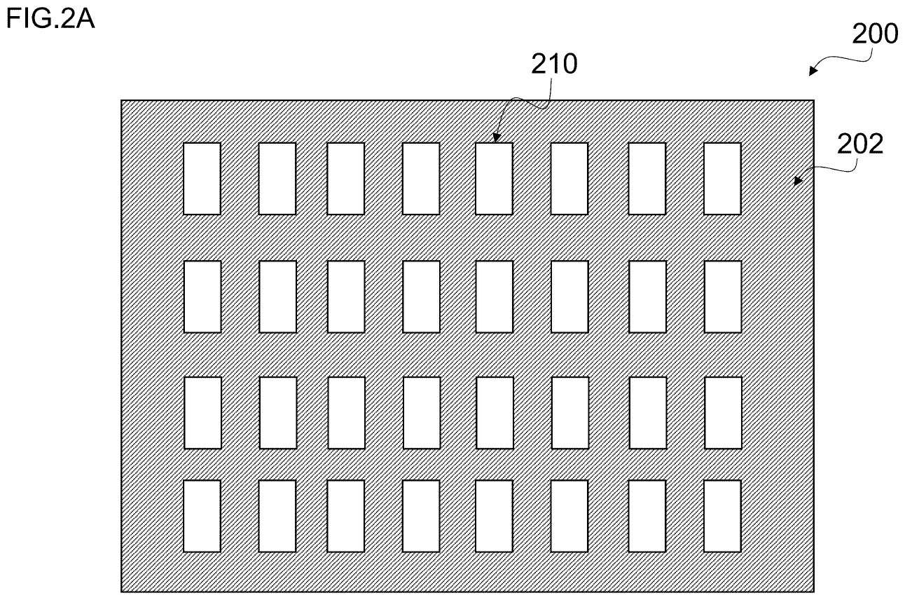

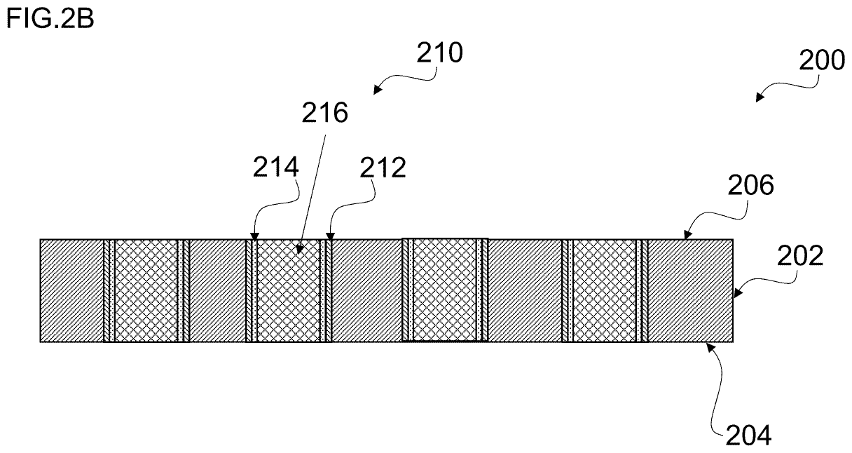

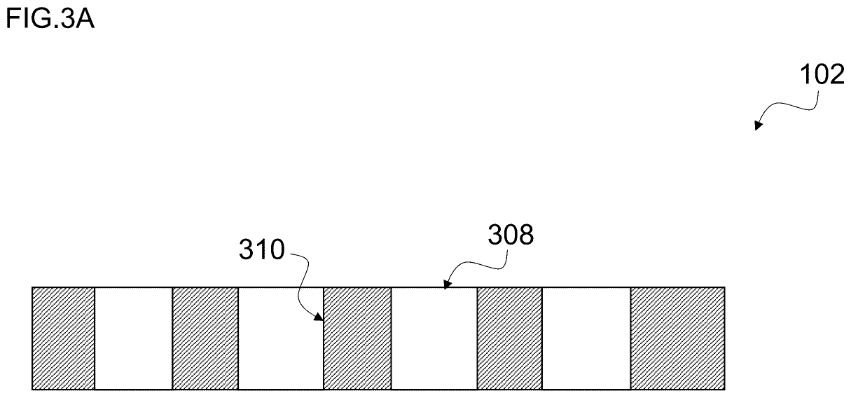

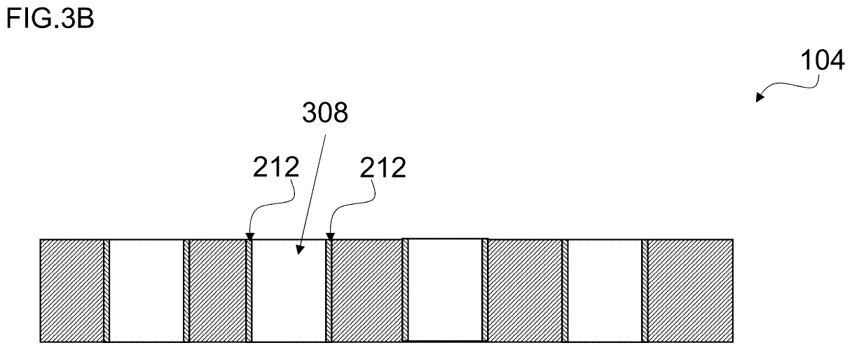

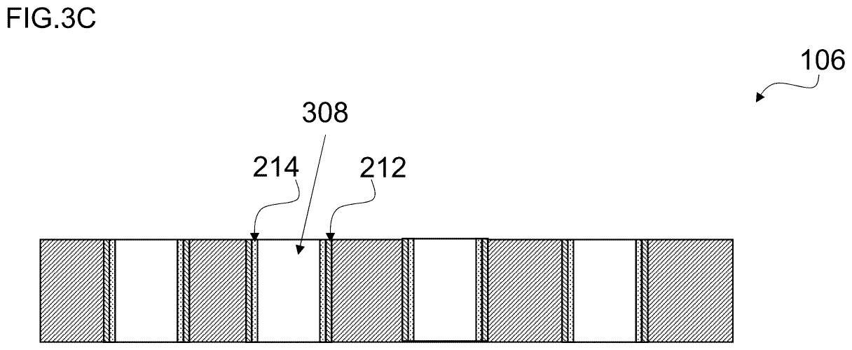

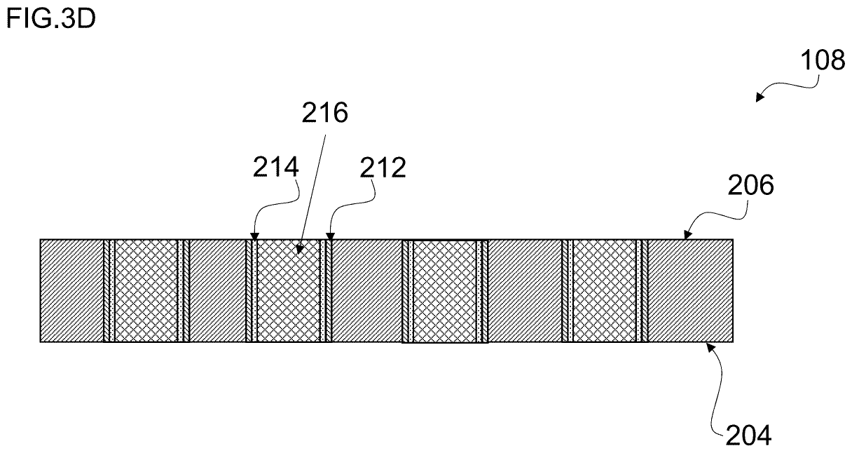

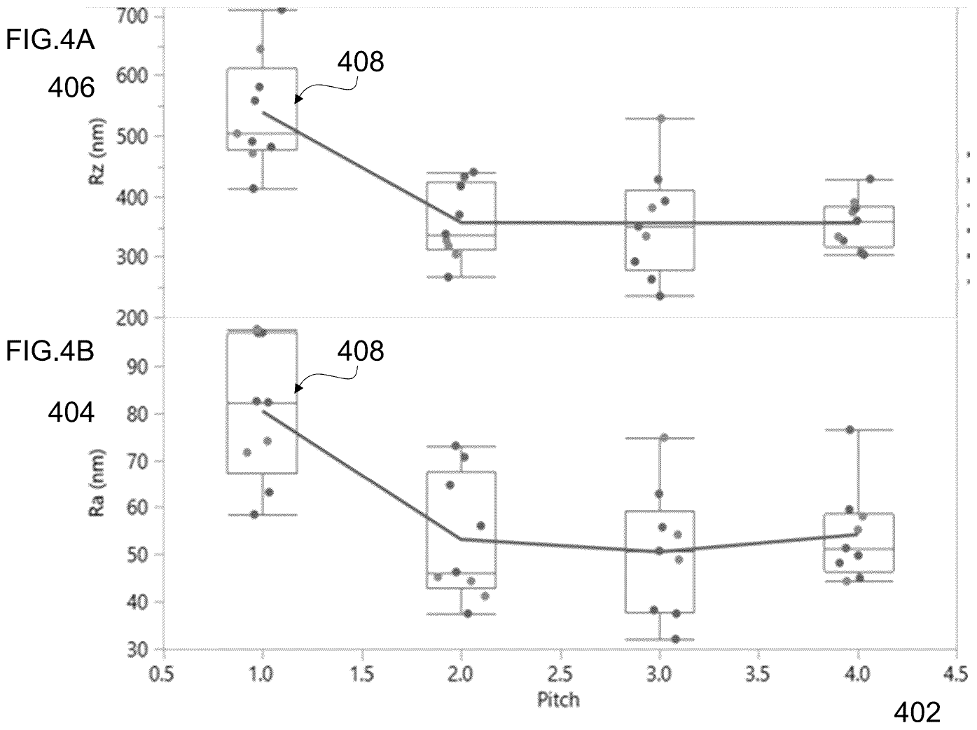

FIG. 1 shows a flow diagram of a method 100 for manufacturing a structured substrate 200 illustrated in a schematic top view in FIG. 2A and in a schematic cross-sectional view in FIG. 2B. FIG. 3A to FIG. 3D show cross-sections of the substrate 202 illustrating the method for forming the structured substrate 200.

The structured substrate 200 may include a substrate 202 having a first surface 204 coplanar to a second surface 206 and a plurality of openings 308 extending from the first surface 204 towards the second surface 206 (see FIG. 3A). The substrate 202 may be a glass substrate 202, e.g. a borosilcate substrate, an aluminiosilciate substrate, or a fused silica substrate. The substrate 202 may be panel having large dimensions, e.g. having a length of at least 30 cm and a width of at least 30 cm. The openings 308 may be through holes, e.g. extending from the first surface 204 to the second surface 206 through the substrate 202. The openings 308 may have length of at least 50 μm and a width of at least 50 μm, for example. The plurality of openings 308 may include more than 1,000 openings, e.g. more than 100,000 openings. A planarization layer 212 may be formed directly on a sidewall 310 of the opening, respectively (see FIG. 3B). A seed layer 214 may be formed directly on the planarization layer 212, respectively (see FIG. 3C). A filling structure 216 may be formed on the seed layer 214 and may filled at least in part the openings, respectively (see FIG. 3D). This way, a via 210 may be formed, respectively, and the structured substrate 200 may include a plurality of vias 210. The vias 210 may be formed in parallel, e.g. at the same time, in the substrate 202.

In other words, the openings 308 filled with filling structure 216, may be vias 210. As an example, the substrate 202 may be a glass substrate 202 and the openings may be through holes, and the openings filled with plating layer 216 may be through-glass-vias (TGV) 210.

The method 100 may include forming 102 a plurality of openings 310 extending from a first surface 204 of the substrate 202 towards a second surface 206 of the substrate 202. The first surface 204 may be coplanar to the second surface 206. Each of the openings may include a sidewall 310. The openings 308 may be formed using a laser assisted HF (hydrofluoric acid) etching process or a laser assisted NaOH (sodium hydroxide)-etching process. The laser pulses used for forming the openings may have pulse length in a range of a few picoseconds (ps). The laser assisted etching (device) may be a means for forming a plurality of openings 308 extending from a first surface 204 of the substrate 202 towards a second surface 206 of the substrate 202.

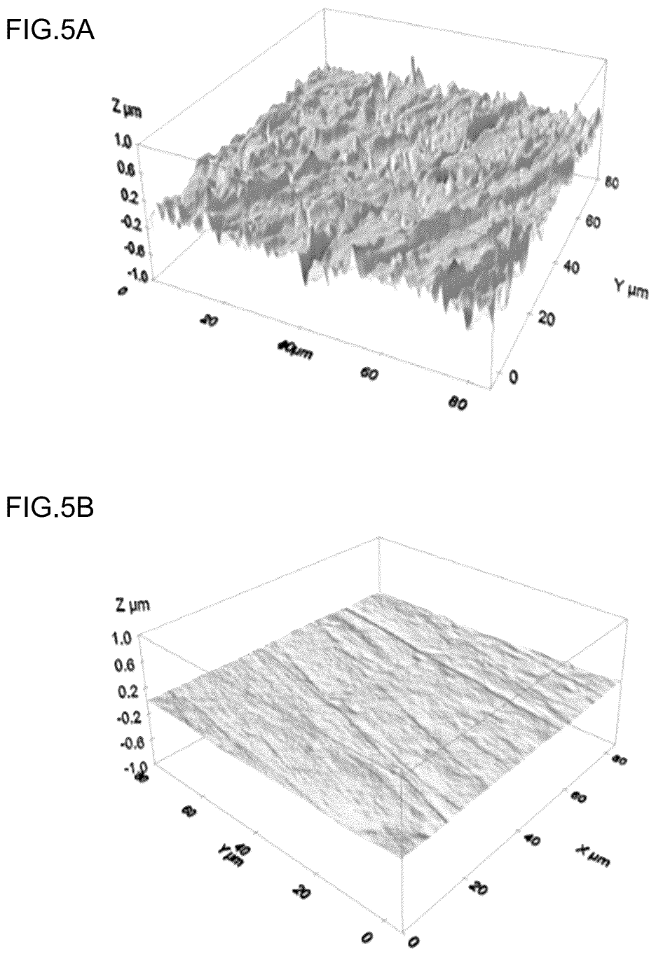

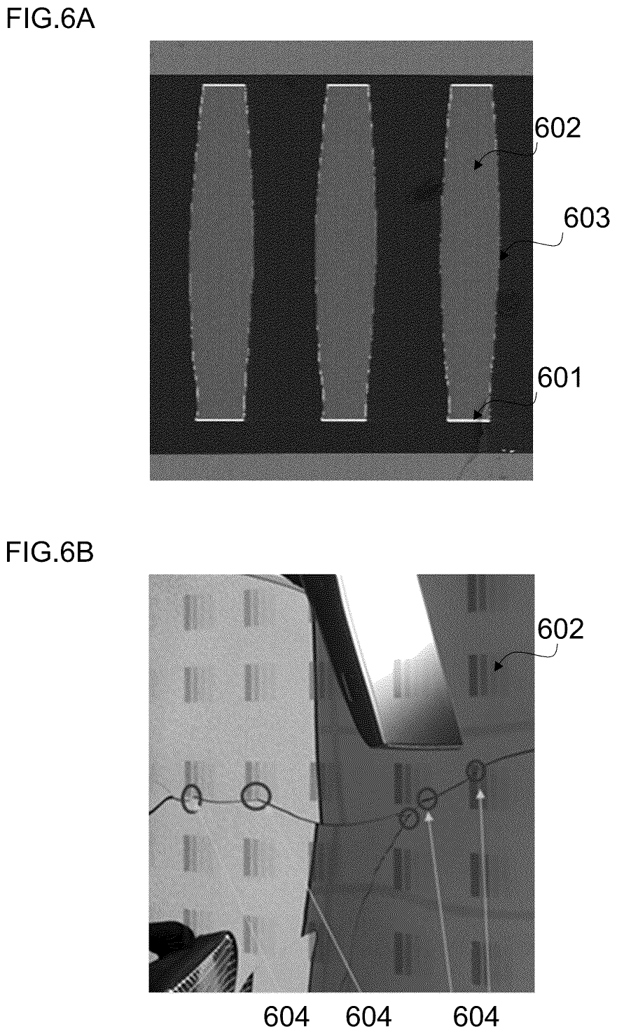

The method 100 may further include forming 104 a planarization layer 212 at least on the sidewall 310 of the openings 308. The planarization layer 212 may reduce the roughness of the sidewall 310. The planarization layer 212 may be formed from hydrogen silsesquioxane, for example. In embodiments where hydrogen silsesquioxane the planarization layer includes silicon and oxygen. The effect of silsesquioxane for planarization is illustrated in FIG. 5A—a surface without planarization layer—and FIG. 5B—a surface with planarization layer.

The planarization layer 212 may be formed using a wet chemical application method, e.g. a spray coating or dip coating of the substrates having the plurality of openings. The wet chemical application (device) may be a means for forming a planarization layer 212 at least on the sidewall 210 of the openings 308. A surface of the sidewall 310 of an opening 308 has a first roughness value, e.g. average roughness, and a surface of the planarization layer 212 has a second roughness value, e.g. average roughness. The second roughness value may be lower than the first roughness value. The opening 310 formed using a laser assisted etching method may allow to form the plurality of openings in a quick and precise manner. However, the laser assisted etching method may generate a relatively high first roughness value.

Forming 104 the planarization layer 212 may include a thermal annealing process. The thermal annealing process may include a temperature of at least 600° C., e.g. ≥600° C. for a borosilicate glass substrate. The thermal annealing process may include a temperature at or above a glass transition temperature of the material of the planarization layer 212. Alternatively, or in addition, forming the planarization layer 212 may include a heating of the material of the planarization layer 212 using a laser, in particular a CO2-laser. The laser heating may be performed successively for subsets of the openings of the plurality of openings.

The planarization layer 212 may be further formed on at least one of the first surface 204 and the second surface 206. The method may further include removing the planarization layer 212 from the respective one of the first surface 204 and the second surface 206. The planarization layer 212 may be removed from the respective one of the first surface 204 and the second surface 206 before the seed layer 214 may be formed.

The method 100 may further include forming 106 a seed layer 214 on the planarization layer 212. The seed layer 214 may include one or more sub-layers, e.g. a first sub-layer, e.g. a titanium (Ti) sub-layer, directly on the planarization layer 212, and a second sub-layer, e.g. a copper (Cu) sub-layer, directly on the first sub-layer. Thus, the seed layer may include a Ti—Cu-layer stack structure, for example. The application (device) for depositing the seed layer 214 to the planarization layer 212 may be a means for forming a seed layer 214 on the planarization layer 212.

The method 100 may further include forming 108 a filling structure 216 on the seed layer 214 and filling the openings 308. The filling structure 216 may substantially fill the openings 308, respectively. The filling structure 214 may be Cu formed on a Cu-seed (sub-)layer. The filling structure 214 may be formed using a physical vapor deposition (PVD), e.g. a sputtering process, e.g. sputtering of Ti and/or Cu. Alternatively, or in addition, a plating process may form the filling structure 216. The plating process may be an electroless plating, for example. The plating (device) may be a means forming a filling structure 216 on the seed layer 214 filling the openings 308. The chemical composition of the plating solution 304, e.g. for electroless plating, may depend on the material at the surface of the substrate and a desired material of the plating layer 210 to be formed.

The substrate 202 may further include a solder resist layer on at least one of the first surface 204 and the second surface 206 (not illustrated). In this case, the surface of the solder resist layer forms the surface of the substrate. In other words, a surface of the solder resist layer may form the surface of the substrate 202 exposed to the forming of the planarization layer. The sidewalls of the openings may be free of solder resist layer.

In the following, various aspects of the present disclosure will be illustrated:

Example 1 is a method for manufacturing a structured substrate, the method including: forming a plurality of openings extending from a first surface of the substrate towards a second surface of the substrate, wherein the first surface is coplanar to the second surface, and wherein each of the openings includes a sidewall; forming a planarization layer at least on the sidewall of the openings; forming a seed layer on the planarization layer; and forming a filling structure on the seed layer filling the openings. A surface of the sidewall of the openings may have a first roughness, and a surface of the planarization layer may have a second roughness. The second roughness may be less than the first roughness.

In Example 2, the subject matter of Example 1 can optionally include that a plating process forms the filling structure.

In Example 3, the subject matter of Example 2 can optionally include that the plating process is an electroless plating.

In Example 4, the subject matter of any one of Examples 1 to 3 can optionally include that the substrate is a glass substrate.

In Example 5, the subject matter of any one of Examples 1 to 4 can optionally include that the openings are through holes extending from the first surface to the second surface.

In Example 6, the subject matter of any one of Examples 1 to 5 can optionally include that the openings filled with filling structure are vias.

In Example 7, the subject matter of any one of Examples 1 to 6 can optionally include that the substrate is a glass substrate and the openings are through holes.

In Example 8, the subject matter of any one of Examples 1 to 7 can optionally include that the filling structure substantially fills the openings, respectively.

In Example 9, the subject matter of any one of Examples 1 to 8 can optionally include that the planarization layer is further formed on at least one of the first surface and the second surface, and the method further. includes removing the planarization layer from the respective one of the first surface and the second surface.

In Example 10, the subject matter of any one of Examples 1 to 9 can optionally include that the planarization layer is removed from the respective one of the first surface and the second surface before the seed layer is formed.

In Example 11, the subject matter of any one of Examples 1 to 10 can optionally include that the substrate is arranged on a mounting structure while forming the planarization layer, the mounting structure substantially covering the first surface of the surface from forming the planarization layer.

In Example 12, the subject matter of any one of Examples 1 to 11 can optionally include that the substrate further includes a solder resist layer, wherein the surface of the solder resist layer forms at least one of the surfaces of the first surface and the second surface.

In Example 13, the subject matter of any one of Examples 1 to 12 can optionally include that the substrate has a length of at least 30 cm and a width of at least 30 cm.

In Example 14, the subject matter of any one of Examples 1 to 13 can optionally include that the openings have a length of at least 50 μm and a width of at least 50 μm, respectively.

In Example 15, the subject matter of any one of Examples 1 to 14 can optionally include that the openings are formed using a laser assisted etching process.

In Example 16, the subject matter of any one of Examples 1 to 15 can optionally include that the planarization layer is formed from hydrogen silsesquioxane.

In Example 17, the subject matter of any one of Examples 1 to 16 can optionally include that forming the planarization layer includes a thermal annealing process

In Example 18, the subject matter of Example 17 can optionally include that the thermal annealing process includes a temperature of at least 600° C.

In Example 19, the subject matter of any one of Examples 17 to 18 can optionally include that the thermal annealing process includes a temperature at or above a glass transition temperature of the material of the planarization layer.

In Example 20, the subject matter of any one of Examples 1 to 19 can optionally include that forming the planarization layer includes a heating of the planarization layer using a laser, in particular a CO2-laser.

Example 21 is a means for manufacturing a structured substrate: a means for forming a plurality of openings extending from a first surface of the substrate towards a second surface of the substrate, wherein the first surface is coplanar to the second surface, and wherein each of the openings includes a sidewall; a means for forming a planarization layer at least on the sidewall of the openings; a means for forming a seed layer on the planarization layer; and a means forming a filling structure on the seed layer filling the openings.

In Example 22, the subject matter of Example 21 can optionally include a means for a plating process forms the filling structure.

In Example 23, the subject matter of any one of Examples 21 to 22 can optionally include that the plating process is an electroless plating.

In Example 24, the subject matter of any one of Examples 21 to 23 can optionally include that the substrate is a glass substrate.

In Example 25, the subject matter of any one of Examples 21 to 24 can optionally include that the openings are through holes extending from the first surface to the second surface.

In Example 26, the subject matter of any one of Examples 21 to 25 can optionally include that the openings filled with filling structure are vias.

In Example 27, the subject matter of any one of Examples 21 to 26 can optionally include that the substrate is a glass substrate and the openings are through holes.

In Example 28, the subject matter of any one of Examples 21 to 27 can optionally include that the filling structure substantially fills the openings respectively.

In Example 29, the subject matter of any one of Examples 21 to 28 can optionally include that the planarization layer is further formed on at least one of the first surface and the second surface, and the means further includes a means for removing the planarization layer from the respective one of the first surface and the second surface.

In Example 30, the subject matter of any one of Examples 21 to 29 can optionally include that the planarization layer is removed from the respective one of the first surface and the second surface before the seed layer is formed.

In Example 31, the subject matter of any one of Examples 21 to 30 can optionally include that the substrate is arranged on a mounting structure while forming the planarization layer, the mounting structure substantially covering the first surface of the surface from forming the planarization layer.

In Example 32, the subject matter of any one of Examples 21 to 31 can optionally include that the substrate further includes a solder resist layer, wherein the surface of the solder resist layer forms at least one of the surfaces of the first surface and the second surface.

In Example 33, the subject matter of any one of Examples 21 to 32 can optionally include that the substrate has a length of at least 30 cm and a width of at least 30 cm.

In Example 34, the subject matter of any one of Examples 21 to 33 can optionally include that the openings have a length of at least 50 μm and a width of at least 50 μm, respectively.

In Example 35, the subject matter of any one of Examples 21 to 34 can optionally include that the openings are formed using a laser assisted etching process.

In Example 36, the subject matter of any one of Examples 21 to 35 can optionally include that the planarization layer is formed from hydrogen silsesquioxane.

In Example 37, the subject matter of any one of Examples 21 to 36 can optionally include that forming the planarization layer includes a thermal annealing process.

In Example 38, the subject matter of any one of Examples 21 to 37 can optionally include that the thermal annealing process includes a temperature of at least 600° C.

In Example 39, the subject matter of any one of Examples 21 to 37 can optionally include that the thermal annealing process includes a temperature at or above a glass transition temperature of the material of the planarization layer.

In Example 40, the subject matter of any one of Examples 21 to 39 can optionally include that forming the planarization layer includes a heating of the planarization layer using a laser, in particular a CO2-laser.

Example 41 is a structured substrate, including: a plurality of openings extending from a first surface of a substrate towards a second surface of the substrate, wherein the first surface is coplanar to the second surface, and wherein each of the openings comprises a sidewall; a planarization layer at least on the sidewall of the openings; a seed layer on the planarization layer; and a filling structure on the seed layer filling the openings.

In Example 42, the subject matter of Example 41 can optionally include that the substrate is a glass substrate.

In Example 43, the subject matter of any one of Examples 41 to 42 can optionally include that the openings are through holes extending from the first surface to the second surface.

In Example 44, the subject matter of any one of Examples 41 to 43 can optionally include that the openings filled with filling structure are vias.

In Example 45, the subject matter of any one of Examples 41 to 44 can optionally include that the substrate is a glass substrate and the openings are through holes.

In Example 46, the subject matter of any one of Examples 41 to 45 can optionally include that the filling structure substantially fills the openings, respectively.

In Example 47, the subject matter of any one of Examples 41 to 46 can optionally include that the substrate further includes a solder resist layer, wherein the surface of the solder resist layer forms at least one of the surfaces of the first surface and the second surface.

In Example 48, the subject matter of any one of Examples 41 to 47 can optionally include that the substrate has a length of at least 30 cm and a width of at least 30 cm.

In Example 49, the subject matter of any one of Examples 41 to 48 can optionally include that the openings have a length of at least 50 μm and a width of at least 50 μm, respectively.

In Example 50, the subject matter of any one of Examples 41 to 49 can optionally include that the planarization layer is formed from hydrogen silsesquioxane.

Example 51 is a glass substrate, including: at least one planar surface and a side surface coupled to the planar surface via an edge; and a planarization layer at least on the side surface of the glass substrate. A surface of the side surface may have a first roughness, and a surface of the planarization layer may have a second roughness. The second roughness may be less than the first roughness.

In Example 52, the subject matter of Example 51 can optionally include that the planarization layer is formed from hydrogen silsesquioxane.

In Example 53, the subject matter of Example 51 or 52 can optionally include that one or more integrated circuits on the planar surface.

Example 54 is a method, including: forming a plurality of openings extending from a first surface of a substrate towards a second surface of the substrate, wherein the first surface is coplanar to the second surface, wherein the substrate includes glass, and wherein each of the openings includes a sidewall; forming a first layer at least on the sidewall of the openings; forming a second layer on the first layer, wherein the second layer includes titanium; and depositing metal on the second layer to at least partially fill the openings. A surface of the sidewall of the openings may have a first roughness, and a surface of the first layer may have a second roughness. The second roughness may be less than the first roughness. The first layer may be the planarization layer and the second layer may be the seed layer as stated above, for example. The method may include features of any one of Examples 1 to 20.

In Example 55, the subject matter of Example 54 can optionally include that depositing the metal includes plating copper on the second layer.

In Example 56, the subject matter of Example 54 or 55 can optionally include that plating copper includes electrolessly plating copper.

In Example 57, the subject matter of any one of Examples 54 to 56 can optionally include that the substrate includes borosilicate glass.

In Example 58, the subject matter of any one of Examples 54 to 57 can optionally include that the openings are through holes extending from the first surface to the second surface.

In Example 59, the subject matter of any one of Examples 54 to 58 can optionally include that the openings are vias.

In Example 60, the subject matter of any one of Examples 54 to 59 can optionally include that depositing the metal substantially fills the openings respectively.

In Example 61, the subject matter of any one of Examples 54 to 60 can optionally include that the first layer includes a planarization layer, wherein the planarization layer is further formed on at least one of the first surface and the second surface, and wherein the method further includes removing the planarization layer from the respective one of the first surface and the second surface.

In Example 62, the subject matter of any one of Examples 54 to 61 can optionally include that the method further includes removing the planarization layer from the respective one of the first surface and the second surface before forming the second layer.

In Example 63, the subject matter of any one of Examples 54 to 62 can optionally include that the substrate further includes a solder resist layer, wherein the surface of the solder resist layer forms at least one of the surfaces of the first surface and the second surface.

In Example 64, the subject matter of any one of Examples 54 to 63 can optionally include that the openings have a length of at least 50 μm and a width of at least 50 μm, respectively.

In Example 65, the subject matter of any one of Examples 54 to 56 can optionally include that the openings are formed using a laser assisted etching process.

In Example 66, the subject matter of any one of Examples 54 to 65 can optionally include that the first layer is formed from hydrogen silsesquioxane.

In Example 67, the subject matter of any one of Examples 54 to 66 can optionally include that forming the first layer includes a thermal annealing process.

In Example 68, the subject matter of Example 67 can optionally include that the thermal annealing process includes a temperature at or above a glass transition temperature of the material of the first layer.

Example 69 is a means for manufacturing, including: a means for forming a plurality of openings extending from a first surface of a substrate towards a second surface of the substrate, wherein the first surface is coplanar to the second surface, wherein the substrate includes glass, and wherein each of the openings includes a sidewall; a means for forming a first layer at least on the sidewall of the openings; a means for forming a second layer on the first layer, wherein the second layer includes titanium; and a means for depositing a metal on the second layer to at least partially fill the openings. The Example may further include features of any one of Examples 21 to 40.

In Example 70, the subject matter of Example 69 can optionally include that the first layer is further formed on at least one of the first surface and the second surface, and the means further include means for removing the first layer from the respective one of the first surface and the second surface.

Example 71 is a glass substrate, including: at least one planar surface and a side surface coupled to the planar surface via an edge; and a first layer at least on the side surface of the glass substrate. A surface of the side surface of the substrate may have a first roughness, and a surface of the first layer may have a second roughness. The second roughness may be less than the first roughness. The first layer may be the planarization layer as stated above, for example. The method may include features of any one of Examples 1 to 20.

In Example 72, the subject matter of Example 71 can optionally include that the first layer is formed from hydrogen silsesquioxane.

In Example 73, the subject matter of Example 71 or 72 can optionally include one or more integrated circuits on the planar surface

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method comprising:
forming a plurality of openings extending from a first surface of a substrate towards a second surface of the substrate, wherein the first surface is coplanar to the second surface, wherein the substrate comprises glass, and wherein each of the openings comprises a sidewall;
forming a first layer at least on the sidewall of the openings;
forming a second layer on the first layer, wherein the second layer comprises titanium; and
depositing metal on the second layer to at least partially fill the openings.

2. The method of claim 1, wherein depositing the metal comprises plating copper on the second layer.

3. The method of claim 2, wherein plating copper comprises electrolessly plating copper.

4. The method of claim 1, wherein the substrate comprises borosilicate glass.

5. The method of claim 1, wherein the openings are through holes extending from the first surface to the second surface.

6. The method of claim 1, wherein the openings are vias.

7. The method of claim 1, wherein depositing the metal substantially fills the openings respectively.

8. The method of claim 1, wherein the first layer comprises a planarization layer, wherein the planarization layer is further formed on at least one of the first surface and the second surface, and wherein the method further comprises removing the planarization layer from the respective one of the first surface and the second surface.

9. The method of claim 8, wherein the method further comprises removing the planarization layer from the respective one of the first surface and the second surface before forming the second layer.

10. The method of claim 1, wherein the substrate further comprises a solder resist layer, wherein the surface of the solder resist layer forms at least one of the surfaces of the first surface and the second surface.

11. The method of claim 1, wherein the openings have a length of at least 50 μm and a width of at least 50 μm, respectively.

12. The method of claim 1, wherein the openings are formed using a laser assisted etching process.

13. The method of claim 1, wherein the first layer is formed from hydrogen silsesquioxane.

14. The method of claim 1, wherein forming the first layer comprises a thermal annealing process.

15. The method of claim 14, wherein the thermal annealing process comprises a temperature at or above a glass transition temperature of the material of the first layer.

16. A means for manufacturing, comprising:
a means for forming a plurality of openings extending from a first surface of a substrate towards a second surface of the substrate, wherein the first surface is coplanar to the second surface, wherein the substrate comprises glass, and wherein each of the openings comprises a sidewall;
a means for forming a first layer at least on the sidewall of the openings;
a means for forming a second layer on the first layer, wherein the second layer comprises titanium; and
a means for depositing a metal on the second layer to at least partially fill the openings.

17. The means of claim 16, wherein the first layer is further formed on at least one of the first surface and the second surface, and the means further. comprises means for removing the first layer from the respective one of the first surface and the second surface.

18. A glass substrate, comprising:
at least one planar surface and a side surface coupled to the planar surface via an edge; and
a first layer at least on the side surface of the glass substrate.

19. The glass substrate of claim 18, wherein the first layer is formed from hydrogen silsesquioxane.

20. The glass substrate of claim 18, further comprising one or more integrated circuits on the planar surface.
